(19) United States
(12) Patent Application Publication
(10) Pub. No.: US 2008/0153010 A1
(43) Pub. Date: Jun. 26, 2008

(54) METHOD FOR DEPOSITING REFLECTIVE MULTILAYER FILM OF REFLECTIVE MASK BLANK FOR EUV LITHOGRAPHY AND METHOD FOR PRODUCING REFLECTIVE MASK BLANK FOR EUV LITHOGRAPHY

(75) Inventor: Takashi SUGIYAMA, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: ASAHI GLASS COMPANY., LTD., Tokyo (JP)

(21) Appl. No.: 12/034,319

(22) Filed: Feb. 20, 2008

Related U.S. Application Data
(63) Continuation of application No. PCT/JP2006/322787, filed on Nov. 9, 2006.

(51) Int. Cl. G03F 1/00

(52) U.S. Cl. 430/5

(57) ABSTRACT

A method for depositing, on a substrate, a reflective multilayer film of a reflective mask blank for EUV lithography by sputtering, comprises:
depositing a reflective multilayer film in such a state that a substrate has been deformed so as to be subjected to a stress, which is directed to the opposite direction to a stress applied to the substrate by deposition of the reflective multilayer film; and
returning the substrate to the shape before deformation, after deposition of the reflective multilayer film.

### TECHNICAL FIELD

The present invention relates to a method for depositing a multilayer film on a substrate. More specifically, the present invention relates to a method for depositing, on a substrate, a reflective multilayer film of a reflective mask blank (hereinbelow, referred to as “EUV mask blank”) for EUV (Extreme Ultra Violet) lithography to be used for semiconductor manufacturing, and a method for producing the EUV mask blank.

### BACKGROUND ART

In the semiconductor industry, a photolithography method using visible light or ultraviolet light has been employed as a technique for writing, on a Si substrate or the like, a fine pattern, which is required for writing an integrated circuit comprising such a fine pattern. However, the conventional exposure techniques using light exposure have been close to the exposure limit while semiconductor devices have had finer patterns at an accelerated pace. In the case of light exposure, it is said that the resolution limit of a pattern is about ½ of an exposure wavelength, and that even if an immersion method is employed, the resolution limit is about ¼ of an exposure wavelength. Even if an immersion method using an ArF laser (193 nm) is employed, it is estimated that the resolution limit is about 45 nm. From this point of view, EUV lithography, which is an exposure technique using EUV light having a shorter wavelength than ArF lasers, has been considered as being promising as the exposure technique for 45 nm or below. In this Description, it should be noted that the phrase “EUV light” means a ray having a wavelength in a soft X ray region or a vacuum ultraviolet ray region, specifically a ray having a wavelength of about 10 to 20 nm, in particular, of about 13.5 nm±0.3 nm.

It is impossible to use EUV light in conventional dioptric systems as in photolithography using visible light or ultraviolet light since EUV light is apt to be absorbed by any substances and since EUV light has a refractive index close to 1. For this reason, a catoptric system, i.e., a combination of a reflective photomask and a mirror, is employed in EUV light lithography.

A mask blank is a stacked member for fabrication of a photomask, which has not been patterned yet. When a mask blank is used for a reflective photomask, the mask blank has a structure wherein a substrate made of glass or the like has a reflective layer for reflecting EUV light and an absorbing layer for absorbing EUV light, formed thereon in this order. The reflective layer normally comprises a reflective multilayer film, which comprises layers of a high-refractive material and layers of a low-refractive material alternately stacked to increase a light reflectance when irradiating a film surface with a ray, more specifically when irradiating a film surface with EUV light. In such a reflective multilayer film, the high-refractive material commonly comprises Mo, and the low-refractive material commonly comprises Si. Although such a reflective multilayer film has been deposited by magnetron sputtering (see JP-A-2002-222764), it is gradually dominant to deposit such a reflective multilayer film by ion beam sputtering from the viewpoint of being capable of obtaining a film, which is less defective and has a high precision (see JP-A-2004-246366).

On the other hand, the absorbing layer comprises a material having a high absorption coefficient in connection with EUV light, such as a material containing Cr or Ta as the main component, and the absorbing layer is normally deposited by magnetron sputtering (see JP-A-2004-246366, JP-A-2002-319542, JP-A-2004-6798, JP-A-2004-6799 and JP-A-2004-39884).

When a thin film is deposited on a substrate, a compressive stress or a tensile stress is caused in the deposited film in some cases. The substrate is liable to be deformed by being subjected to such a compressive stress or a tensile stress. The occurrence of a compressive stress or a tensile stress has caused no problem in the past since the substrate for a photomask, which normally comprises a substrate made of low-expansion glass, is only slightly deformed even when such a stress is applied.

However, a slight deformation in a substrate (a deformation in a substrate caused by application of a stress), which has not been regarded as being a problem in the past, has become problematic since it is required to make a pattern finer.

JP-A-2004-29736 discloses a method for producing a mask blank and a mask for writing a pattern, wherein even when a thin film per se has a film stress, the mask blank can have a desired flatness, and it is possible to prevent the positional accuracy of a mask from being reduced and to prevent the occurrence of a pattern shift or pattern defect when writing the pattern, and a method for determining the flatness of a transparent substrate for electronic devices to be used therefor and a method for producing the transparent substrate. In the methods disclosed in JP-A-2004-29736, it is proposed to determine the flatness of the transparent substrate for electronic devices so as to provide the substrate with a desired flatness in consideration of a flatness variation caused by the film stress in a thin film deposited on the principal surface of the substrate to be used as a mask blank and to adjust the flatness of the substrate by polishing the substrate surface into a convex shape or a concave shape according to the determined flatness.

JP-A-2003-501823 has proposed to deposit a high-dielectric coating on the backside of a substrate to facilitate electrostatic chucking in order to correct for a warp caused by the stress imbalance between an EUV mask substrate made of a low thermal expansion material and a multilayer coating deposited on the substrate. JP-A-2003-501823 has also proposed to form a stress balancing layer between an EUV mask substrate and a material layer deposited on the mask substrate in order to prevent the occurrence of a warp caused by the stress imbalance between the EUV mask substrate and the material layer deposited on the substrate.

### DISCLOSURE OF INVENTION

### Problems that the Invention is to Solve

However, in the method disclosed in JP-A-2004-29736, not only it is difficult but also it takes much time to polish the substrate surface into a predetermined shape (a convex shape or a concave shape) according to a variation in the flatness caused by the film stress in a thin film. When such polishing is done, it is quite difficult to polish the substrate surface in estimation of not only causing the flatness of the substrate to be satisfied the specifications of an EUV mask blank but also causing the wedge angles and the local slopes to be satisfied the specifications of the EUV mask blank

When an EUV mask blank is produced, a plurality of films, which have different compositions, are deposited on a substrate. For example, a reflective layer is a reflective multilayer film comprising high refractive layers and low refractive layers alternately stacked therein. An absorbing layer comprises a layer having a high absorption coefficient in connection with EUV light. The stresses generated in these films are not always stresses having the same inclination as one another. In some cases, a film with a tensile stress generated therein and a film with a compressive stress generated therein are stacked. In such cases, it is practically impossible to polish the substrate surface so as to cope with the stresses generated in all films. For this reason, the method disclosed in JP-A-2004-29736 has proposed to polish the substrate surface so as to cope with the stresses generated at the time of completing deposition of all films (the total of the stresses generated in the respective films).

This means that when the method disclosed in JP-A-2004-29736 is applied to an EUV mask blank, it is probable that the shape of the polished substrate surface fails to be fitted to the stress generated in a deposited film during the film deposition process. For example, there could be a situation where although the substrate surface is formed in such a shape to cope with a case where a tensile stress is generated in a film, a compressive stress is generated in the deposited film. When the substrate is removed from a holding means, such as an electrostatic chuck or a holder, in such a situation, the deformation of the substrate caused by the stress in the film is rather worse than a case where the film is deposited on a flat substrate surface, because the polished substrate surface fails to be fitted to the stress generated in the deposited film.

On the other hand, when according to the method disclosed in JP-A-2003-501823, a high dielectric coating is deposited on the backside of a substrate to facilitate electrostatic chucking of the substrate, the stress imbalance between the substrate and the material layer is not improved, although the substrate is not warped when being held by an electrostatic chuck. For this reason, when the substrate is removed from the electrostatic chuck, there is a possibility of warping the substrate by a stress imbalance caused between the substrate and the material layer.

When an EUV mask blank is produced, the kinds and the thicknesses of the films deposited on the EUV mask substrate are limited in terms of optical characteristics or another reason. For this reason, the kinds of the material used as the stress balancing layer deposited between the substrate and the material layer, and the thickness of the stress balancing layer are limited accordingly. Therefore, it has been difficult to sufficiently improve the stress imbalance between the substrate and the material layer.

It is an object of the present invention to solve the above-mentioned problems and to provide a method for depositing a multilayer film, which is capable of preventing deformation of a substrate to provide the substrate with a good flatness, even if a stress is applied to the substrate by deposition of a multilayer film. More specifically, it is an object of the present invention to provide a method for depositing a reflective multilayer film for an EUV mask blank, which is capable of preventing deformation of a substrate to provide the substrate with a good flatness, even if a stress is applied to the substrate by deposition of a reflective multilayer film. It is another object of the present invention to provide a method for producing an EUV mask blank, which is capable of preventing deformation of a substrate to provide the substrate with a good flatness, even if a stress is applied to the substrate by deposition of a buffer layer and an absorbing layer.

### Means for Solving the Problem

In order to attain the objects, the present invention provides a method for depositing a multilayer film on a substrate, comprising:

depositing a multilayer film in such a state that a substrate has been deformed so as to be subjected to a stress, which is directed to the opposite direction to a stress applied to the substrate by deposition of the multilayer film; and

returning the substrate to the shape before deformation, after deposition of the multilayer film.

The present invention also provides a method for depositing, on a substrate, a reflective multilayer film of a reflective mask blank for EUV lithography by sputtering, comprising:

depositing a reflective multilayer film in such a state that a substrate has been deformed so as to be subjected to a stress, which is directed to the opposite direction to a stress applied to the substrate by deposition of the reflective multilayer film; and

returning the substrate to the shape before deformation, after deposition of the reflective multilayer film (hereinbelow, referred to as “the method for depositing a reflective multilayer film, according to the present invention”).

It is preferred that the substrate that has been returned to the shape before deformation have a flatness of 100 nm or below in the method according to the present invention.

It is preferred that in order to deposit the reflective multilayer film in such a state that the substrate has been deformed in the method according to the present invention, the substrate be held by a first electrostatic chuck, which has a contact surface with the substrate, formed in a shape corresponding to the shape of the substrate after deformation.

It is preferred that the first electrostatic chuck have a chucking force of 0.5 kPa or above and a Young's modulus of 10 GPa or above in the method according to the present invention.

It is preferred that the contact surface of the first electrostatic chuck, on which the substrate is held, have slightly smaller dimensions than those of the substrate in the method according to the present invention.

It is preferred that the substrate have a specific rigidity of 3.0×10⁷ m²/s² or above and a Poisson's ratio of 0.16 to 0.25 in the method according to the present invention.

The present invention also provides a method for producing a reflective mask blank for EUV lithography, comprising:

depositing an absorbing layer on a reflective multilayer film by sputtering after depositing the reflective multilayer film on a substrate by the method for depositing a reflective multilayer film of a reflective mask blank for EUV lithography, according to the present invention;

the method further comprising:

depositing the absorbing layer in such a state that the substrate has been deformed so as to be subjected to a stress, which is directed to the opposite direction to a stress applied to the substrate by deposition of the absorbing layer; and

returning the substrate to the shape before deformation, after deposition of the absorbing layer.

The present invention also provides a method for producing a reflective mask blank for EUV lithography, comprising:

depositing a buffer layer and an absorbing layer on a reflective multilayer film by sputtering after depositing the reflective multilayer film on a substrate by the method for depositing a reflective multilayer film of a reflective mask blank for EUV lithography, according to the present invention;

the method further comprising:

depositing the buffer layer and the absorbing layer in such a state that the substrate has been deformed so as to be subjected to a stress, which is directed to the opposite direction to a stress applied to the substrate by deposition of the buffer layer and the absorbing layer; and

returning the substrate to the shape before deformation, after deposition of the absorbing layer.

In Description, the method for producing a reflective mask blank for EUV lithography by depositing the absorbing layer on the reflective multilayer film, and the method for producing a reflective mask blank for EUV lithography by depositing the buffer layer and the absorbing layer on the reflective multilayer film, which are described above, are collectively called “the method for producing an EUV mask blank”.

It is preferred that the substrate that has been returned to the shape before deformation have a flatness of 100 nm or below in the method for producing an EUV mask blank.

It is preferred that in order to deposit the absorbing layer, or the buffer layer and the absorbing layer in such a state that the substrate has been deformed, the substrate be held by a second electrostatic chuck, which has a contact surface with the substrate, formed in a shape corresponding to the shape of the substrate after deformation in the method for producing an EUV mask blank.

It is preferred that the second electrostatic chuck have a chucking force of 0.5 kPa or above and a Young's modulus of 10 GPa or above in the method for producing an EUV mask blank.

In accordance with the method for depositing a reflective multilayer film, according to the present invention, the stress that is applied to a substrate by deposition of a reflective multilayer film can be reduced by a stress (hereinbelow, referred to as “the first stress”), which is directed to the opposite direction to the direction of the stress applied to the substrate by deposition of the reflective multilayer film. Thus, it is not probable that the substrate is deformed after film deposition by the stress applied to the substrate by deposition of the reflective multilayer film. As a result, it is possible to provide the reflective multilayer film of an EUV mask blank with an excellent flatness, more specifically with a flatness of 100 nm or below.

In accordance with a first mode of the method for producing an EUV mask blank, according to the present invention, the stress that is applied to a substrate by deposition of an absorbing layer can be reduced by a stress (hereinbelow, referred to as “the second stress”), which is directed to the opposite direction to the direction of the stress applied to the substrate by deposition of the absorbing layer. Thus, it is not probable that the substrate is deformed after film deposition by the stress applied to the substrate by deposition of the absorbing layer. As a result, it is possible to provide the EUV mask blank with an excellent flatness, more specifically with a flatness of 100 nm or below.

In accordance with a second mode of the method for producing an EUV mask blank, according to the present invention, the stress that is applied to the substrate by deposition of a buffer layer and an absorbing layer can be reduced by a stress (hereinbelow, referred to as “the third stress”), which is directed to the opposite direction to the direction of the resultant of the stresses applied to the substrate by deposition of the buffer layer and the absorbing layer (hereinbelow, also referred to as “the stresses applied to the substrate by deposition of the buffer layer and the absorbing layer) Thus, it is not probable that the substrate is deformed after film deposition by the stresses applied to the substrate by deposition of the buffer layer and the absorbing layer. As a result, it is possible to provide the EUV mask blank with an excellent flatness, more specifically with a flatness of 100 nm or below.

In accordance with the method for depositing a reflective multilayer film, according to the present invention, it is also possible to obtain a reflective multilayer film having a flatness of 100 nm or below by using, as the substrate for deposition, a substrate having a flatness of more than 100 nm.

In accordance with the method for producing an EUV mask blank, according to the present invention, it is also possible to obtain an EUV mask blank having a flatness of 100 nm or below by using, as the substrate for deposition, a substrate having a flatness of more than 100 nm.

When there are no substantial differences in terms of the film thickness and the number of the layers of a reflective multilayer film to deposit, the stress applied to a substrate by deposition of the reflective multilayer film is almost constant since the value of the stress caused by deposition of the reflective multilayer film is substantially determined by the film thickness and the number of the layers. From this point of view, in the method for depositing a reflective multilayer film, according to the present invention, the first stress that is applied to the substrate at the time of depositing the reflective multilayer film is also almost constant. For this reason, it is not necessary to reevaluate the first stress for each substrate, more specifically to change the shape of an electrostatic chuck for each substrate, when implementing the method for depositing a reflective multilayer film, according to the present invention. As a result, it is possible to produce substrates with a reflective multilayer film deposited thereon, with good productivity.

### BRIEF DESCRIPTION OF DRAWINGS

FIGS. 1(a) to (e) are schematic views explaining a method for depositing a reflective multilayer film, according to the present invention and show shapes of a substrate before and after deposition of a reflective multilayer film, wherein FIG. 1(a) shows the substrate, which has not had the reflective multilayer film deposited thereon, FIG. 1(b) shows the substrate, which has had the reflective multilayer film deposited thereon according to a conventional process, FIG. 1(c) shows the substrate, which has been deformed so as to be subjected to the first stress, FIG. 1(d) shows a state where the reflective multilayer film has been deposited on the substrate shown in FIG. 1(c), and FIG. 1(e) shows a state where the substrate has been returned to the shape before deformation, after deposition of the reflective multilayer film;

FIG. 2 is a schematic view of a first electrostatic chuck, which is used for deforming the substrate in the shape shown in FIG. 1(c);

FIGS. 3(a) to (e) are schematic views explaining a method for depositing an EUV mask blank, according to the present invention and show shapes of a substrate before and after deposition of an absorbing layer, wherein FIG. 3(a) shows the substrate, which has not had the absorbing layer deposited thereon, FIG. 3(b) shows the substrate, which has had the absorbing layer deposited on the reflective multilayer film according to a conventional process, FIG. 3(c) shows the substrate, which has been deformed so as to be subjected to the second stress, FIG. 3(d) shows a state where the absorbing layer has been deposited on the reflective multilayer film on the substrate shown in FIG. 3(c), and FIG. 3(e) shows a state where the substrate has been returned to the shape before deformation, after deposition of the absorbing layer; and

FIG. 4 is a schematic view of a second electrostatic chuck, which is used for deforming the substrate in the shape shown in FIG. 3(c).

### BEST MODE FOR CARRYING OUT THE INVENTION

The present invention is directed to a method for depositing a multilayer film on a substrate, which is characterized in that the multilayer film is deposited on the substrate in such a state that the substrate has been deformed so as to be subjected to a stress, which is directed to the opposite direction to the direction of the stress applied to the substrate by deposition of the multilayer film, and that after deposition of the multilayer film, the substrate is returned to the shape before deformation.

First, the method for depositing a reflective multilayer film, according to the present invention will be described. The method for depositing a reflective multilayer film, according to the present invention is the same as the conventional methods in terms of depositing, on a substrate, a reflective multilayer film for an EUV mask blank (hereinbelow, referred to as “the reflective multilayer film) by sputtering, such as magnetron sputtering or ion beam sputtering. However, in the method according to the present invention, the reflective multilayer film is deposited in such a state that the substrate has been deformed so as to be subjected to the first stress.

When the reflective multilayer film is deposited on a substrate by sputtering, such as magnetron sputtering or ion beam sputtering, a stress (normally, a compressive stress) is caused in the reflective multilayer film after deposition, and the stress is applied to the substrate. This stress will be called “the stress applied to the substrate by deposition of the reflective multilayer film” or “the stress caused by deposition of the reflective multilayer film” in Description.

For example, when a Si/Mo reflective multilayer film is deposited by alternately depositing, on a substrate, Si films (layers having a low refractive index and a film thickness of 4.5 nm) and Mo films (layers having a high refractive index and a film thickness of 2.3 nm) in totally 40 to 50 layers as the reflective multilayer film by ion beam sputtering, a compressive stress of 400 to 500 MPa is normally applied to the substrate by deposition of the reflective multilayer film. When the reflective multilayer film is deposited, the substrate is held by an electrostatic chuck or a holder. Even if such a compressive stress of 400 to 500 MPa is normally applied to the substrate by deposition of the reflective multilayer film at this stage, the substrate is not deformed by application of the compressive stress. However, when the substrate is removed from the electrostatic chuck or the holder, the substrate is deformed to some extent by the compressive stress of 400 to 500 MPa caused by deposition of the reflective multilayer film even if the substrate comprises a substrate made of quartz glass and having a high rigidity.

For example, when a compressive stress of from 400 to 500 MPa, which is caused by deposition of a reflective multilayer film, is applied to a SiO₂—TiO₂ glass substrate, which is generally used as the substrate for an EUV mask blank (having outer dimensions of 6 inch (152.4 mm) square, a thickness of 6.3 mm, a coefficient of thermal expansion of 0.2×10⁻⁷/° C., a Young's modulus of 67 GPa and a specific rigidity of 3.1×10⁷ m²/s²), the substrate is deformed so as to be warped in a convex shape having a height of from about 1.9 to 2.1 μm toward the surface for deposition. In the case of an EUV mask blank, the allowable limit of a flatness is 100 nm or below from end to end of the mask blank. The “flatness of a substrate after deposition of a reflective multilayer film means the flatness on the reflective multilayer film.

Although the flatness of a substrate after deposition of a reflective multilayer film is decreased to an allowable limit value or below by heat treatment or the like, there is a possibility that the optical characteristics of the EUV mask blank is degraded by such treatment.

In the method for depositing a multilayer film, according to the present invention, a reflective multilayer film is deposited in such state that the substrate has been deformed so as to be subjected to the first stress. For example, in the above-mentioned case, since a compressive stress of 400 to 500 MPa is applied to a substrate by deposition of a reflective multilayer film, the first stress is a compressive stress having substantially the same magnitude as the just-mentioned compressive stress.

In a case where a reflective multilayer film is deposited in such state that the substrate has been deformed so as to be subjected to the first stress, when the substrate is returned to the original shape after deposition of the reflective multilayer film, the stress that is applied to the substrate by deposition of the reflective multilayer film is reduced to such a degree that the stress applied to the substrate is cancelled by the first stress, although will be described in detail.

The “first stress” means a stress directed to the opposite direction to the direction of the stress applied to the substrate by deposition of the reflective multilayer film as stated above. However, the stress applied to the substrate by deposition of the reflective multilayer film is a two-dimensional stress, while the first stress is supposed to be a three-dimensional stress since the first stress is caused by deforming the substrate. From this point of view, when the above-mentioned definition of “the first stress” is narrowly interpreted, i.e., is literally interpreted, the first stress is not a stress directed to the opposite direction to the direction of the stress applied to the substrate by deposition of the reflective multilayer film in some cases. In this regard, the definition of “the first stress” is broadly interpreted in Description. Specifically, when the stress applied to the substrate by deposition of the reflective multilayer film is a compressive stress as stated above, the first stress comprises a tensile stress having substantially the same magnitude as the stress applied to the substrate by deposition of the reflective multilayer film, or a three-dimensional stress corresponding to the tensile stress. This is also applicable to the second stress and the third stress, which will be described later.

As clearly described, the magnitude of the first stress varies according to the magnitude of the stress applied to a substrate by deposition of a reflective multilayer film in the method for depositing a reflective multilayer film, according to the present invention.

In the method for depositing a reflective multilayer film, according to the present invention, the stress applied to a substrate by deposition of a reflective multilayer film is reduced to preferably 300 MPa or below, more preferably 200 MPa or below and further preferably 100 MPa or below by the first stress. In the method for depositing a reflective multilayer film, according to the present invention, it is preferred that the first stress be equal to the stress applied to a substrate by deposition of a reflective multilayer film.

In order that a substrate is deformed to be subjected to the first stress in the method for depositing a reflective multilayer film, according to the present invention, it is sufficient to deform the substrate in the opposite direction to the direction in which the substrate is deformed by application of a compressive stress caused by deposition of a reflective multilayer film. In the above-mentioned case, a compressive stress is applied to the substrate by deposition of the reflective multilayer film, with the result that the substrate is deformed so as to be warped in a convex state by about 1.9 to 2.1 μm, generally about 1.95 to 2.05 μm toward the surface for deposition. From this point of view, in order that a substrate 1 is subjected to the first stress, it is sufficient that the substrate is deformed so as to be warped in a concave state by about 1.9 to 2.1 μm, preferably about 1.95 to 2.05 μm toward the surface for deposition.

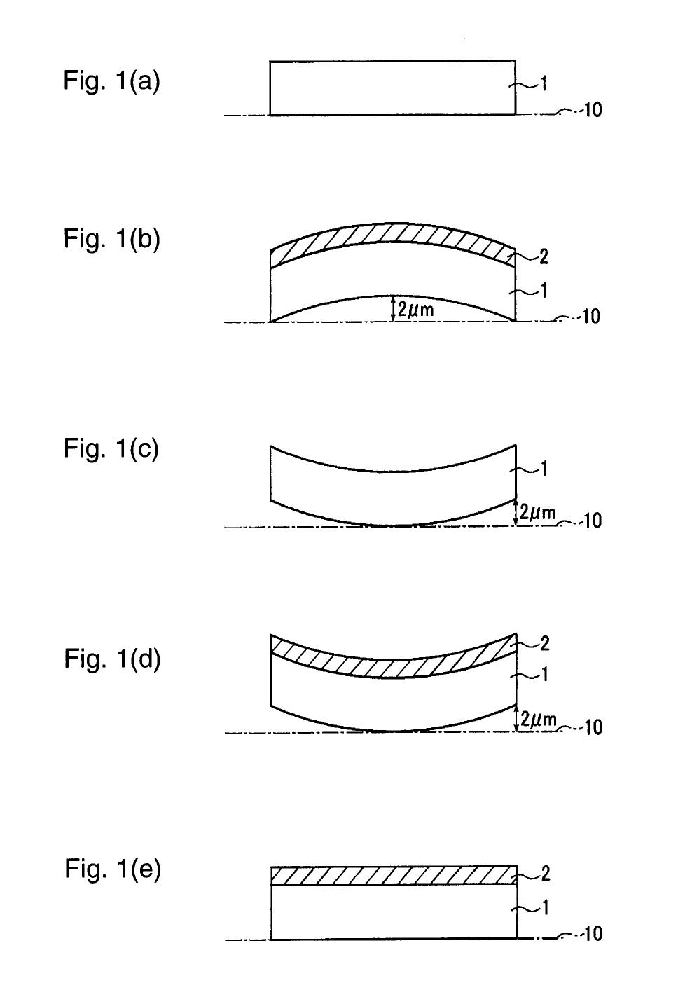

FIGS. 1(a) to (e) are schematic views explaining a method for depositing a reflective multilayer film, according to the present invention and show shapes of a substrate before and after deposition of a reflective multilayer film. FIG. 1(a) shows the substrate 1 before deposition of the reflective multilayer film. As shown in FIG. 1(a), the substrate 1 before deposition of the reflective multilayer film is polished with the aim of a flatness of 0 μm. In FIG. 1(a), a line 10 is an imaginary horizontal line for more clearly showing the presence or absence of a change in the substrate 1. FIG. 1(b) shows the substrate 1 after deposition of a reflective multilayer film 2 according to a conventional process by sputtering. In FIG. 1(b), a compressive stress caused by deposition of the reflective multilayer film 2 is applied to the substrate 1, with the result that the substrate 1 is deformed so as to be warped in a convex state toward the surface for deposition.

FIG. 1(c) shows the substrate 1, which has been deformed so as to be subjected to the first stress in order that the substrate 1 after deposition of the reflective multilayer film 2 is prevented from deformed in the shape shown in FIG. 1(b). In FIG. 1(c), the substrate 1 has been deformed so as to be warped in a concave shape toward the surface for deposition. In the method for depositing a reflective multilayer film, according to the present invention, the reflective multilayer film is deposited by sputtering in such a state that the substrate 1 has been deformed in the shape shown in FIG. 1(c). FIG. 1(d) shows a state wherein the reflective multilayer film 2 has been deposited on the substrate 1 shown in FIG. 1(c).

In the method for depositing a reflective multilayer film, according to the present invention, after the reflective multilayer film 2 has been deposited in such a state that the substrate 1 has been subjected to the first stress as shown in FIG. 1(d), the substrate 1 is returned to the shape before deformation. In order to return the substrate 1 to the shape before deformation from the state shown in FIG. 1(d), the force that has been applied to the substrate 1 for deformation may be removed. Thus, the substrate 1 is returned to the shape before deformation by its restoring force.

FIG. 1(e) shows a state wherein the substrate 1 has been returned to the shape before deformation, after deposition of the reflective multilayer film 2. In the state shown in FIG. 1(e), the compressive stress that is applied to the substrate 1 by deposition of the reflective multilayer film is reduced to such a degree that the stress applied to the substrate is canceled by the first stress. As a result, the substrate 1 is prevented from being deformed by the compressive stress applied to the substrate 1 by deposition of the reflective multilayer film.

In the method for depositing a reflective multilayer film, according to the present invention, there is no particular limitation to the means for depositing the reflective multilayer film 2 in such a state that the substrate 1 has been deformed so as to be subjected to the first stress, i.e., the means for causing the substrate 1 to be deformed so as to be subjected to the first stress. For example, when the substrate 1 is deformed so as to be warped in a concave state toward the surface for deposition shown in FIG. 1(c), the substrate may be deformed so as to be warped in a concave shape toward the surface for deposition by pressing both lateral sides of the substrate 1 shown in FIG. 1(a) toward a central direction in this figure by forces having a certain magnitude. It is preferred that both forces be equal to each other in the central direction.

In order that the reflective multilayer film 2 is deposited in such a state that the substrate 1 has been deformed so as to be subjected to the first stress in the method for depositing a reflective multilayer film, according to the present invention, it is preferred that an electrostatic chuck formed in a specific shape be utilized to hold the substrate 1. In this case, the static chuck is a means for causing the substrate 1 to be deformed so as to be subjected to the first stress.

When a film is deposited on a substrate by sputtering, such as magnetron sputtering or iron beam sputtering, an electrostatic chuck is most commonly utilized as the means for holding the substrate. When a electrostatic chuck is utilized as the means for deforming the substrate, a new means, which is utilized only for deformation of the substrate, does not need to be brought into a system for carrying out sputtering. If such a new means is brought into the system for carrying out sputtering, there is a possibility that sputtered particles, which have been deposited on the means, peel off to contaminate the substrate and the reflective multilayer film. When the electrostatic chuck is utilized as the means for deforming the substrate, it is possible to deposit a film on the entire surface for deposition of the substrate at one time.

In order to cause the substrate 1 to be deformed so as to be subjected to the first stress by such an electrostatic chuck, it is sufficient to utilize a first electrostatic chuck, which has a contact surface with the substrate, formed in such a shape to correspond to the shape of the substrate after deformation.

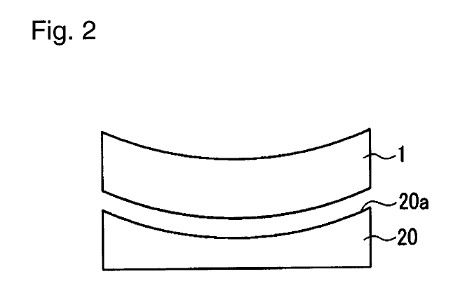

FIG. 2 is a schematic view of such a first electrostatic chuck, which is utilized when the substrate 1 is deformed in the shape shown in FIG. 1(c). FIG. 2 also shows the substrate 1 shown in FIG. 1(c). In the first electrostatic chuck 20 shown in FIG. 2, the contact surface 20a with the substrate 1 corresponds to the shape of the substrate 1 after deformation shown in FIG. 1(c). Specifically, the contact surface 20a is formed in a concave shape so as to correspond to the shape of the surface of the substrate 1 opposite to the surface for deposition (hereinbelow, referred to as “the backside of the substrate 1” in Description), the substrate having been deformed as shown in FIG. 1(c). By holding the substrate 1 on the first electrostatic chuck 20 formed in such a shape, it is possible to deform the substrate 1 in the shape shown in FIG. 1(c). Although the contact surface of the electrostatic chuck per se is formed in a concave shape in FIG. 2, a shaping member, which has a concave shape, may be interposed between an electrostatic chuck and the substrate to provide the required concave surface, the contact surface of the electrostatic chuck being formed in a flat shape. This modification is also covered by the concept of the electrostatic chuck.

When the first electrostatic chuck 20 is formed in such a shape so as to correspond to the shape of the substrate 1 after deformation, it is preferred that the difference between the shape of the substrate 1 after deformation and the shape of the contact surface 20a with the substrate 1 in the first electrostatic chuck 20 be 2 mm or below at the maximum, particularly 1 mm or below, more particularly 0.1 mm or below.

When the substrate is used for producing an EUV mask blank, the substrate comprises a substrate having a high rigidity, such as a quartz glass substrate. From this point of view, the first electrostatic chuck needs to satisfy the following conditions in order to cause such a substrate to be deformed so as to be subjected to the first stress by the electrostatic chuck:

(a) Having a higher rigidity than a substrate to be used for deposition (in terms of Young's modulus or Poisson's ratio)

(b) Having a sufficiently strong chucking force so as to be capable of deforming the substrate

With respect to condition (a), it is preferred that the first electrostatic chuck satisfy the following conditions in terms of Young's modulus and Poisson's ratio:

Young's modulus: 10 GPa or above, preferably 50 GPa or above

Poisson's ratio: 0.4 or below, preferably 0.3 or below

When the first electrostatic chuck 20 has a lower rigidity than the substrate 1, there is a possibility that the electrostatic chuck 20, instead of the substrate 1, is deformed. Although it is impossible to determine the rigidity of the electrostatic chuck based on only the Young's modulus and the Poisson's ratio since the rigidity is also affected by the shape or the size, it is preferred from the viewpoint of increasing the rigidity of the electrostatic chuck that the Young's modulus and the Poisson's ratio be in the above-mentioned ranges, respectively.

In order that the first electrostatic chuck meets the Young's modulus and the Poisson's ratio required as stated above, the electrostatic chuck needs to be made of a material having a high hardness. A surface portion of the electrostatic chuck in contact with a substrate needs to be made of a high-dielectric material, specifically a material having a dielectric constant of 8 or above at 1 MHz.

In order to meet these requirements, the surface portion of such an electrostatic chuck in contact with a substrate comprises a ceramic material, such as alumina, aluminum nitride or silicon carbide.

With respect to condition (b), the first electrostatic chuck has a chucking force of preferably 0.5 kPa or above, more preferably of 1.0 kPa or above. In a case where the first electrostatic chuck has a small chucking force, when a substrate 1 is held on the first electrostatic chuck 20, the substrate 1 fails to be sufficiently deformed in some cases. When the chucking force is in the above-mentioned range, even a substrate having a high rigidity, such as a quartz glass substrate, can be deformed in a desired shape.

In the method for depositing a reflective multilayer film, according to the present invention, there are no particular limitations to the shape and the dimensions of the first electrostatic chuck 20, more specifically, the planar shape and the dimensions of the contact surface 20a of the first electrostatic chuck 20. The contact surface 20a may be formed in a circular planar shape, an elliptical planar shape, a square planar shape, a rectangular planar shape, or another polygonal planar shape, such as a hexagonal planar shape or an octagonal planar shape. It is preferred in terms of a substrate 1 held on the contact surface 20a being deformed in a desired shape that the contact surface 20a be formed in substantially the same as the planar shape of the substrate 1 held on the contact surface 20a.

The dimensions of the contact surface 20a may be larger or smaller than the sizes of the substrate 1 held on the contact surface 20. However, when the contact surface 20a has large dimensions than the substrate 1, there is a possibility that sputtered particles adhere to the contact surface 20a, serving as a contamination source, at the time of depositing a reflective multilayer film by sputtering. When the contact surface 20a is much smaller than the substrate 1, the substrate 1 held on the contact surface 20a fails to be deformed in a desired shape in some cases. From this point of view, it is preferred that the contact surface 20a have slightly smaller dimensions than the substrate 1.

In order to cause the substrate 1 to be deformed so as to be subjected to the first stress by the first electrostatic chuck in the method for depositing a reflective multilayer film, according to the present invention, it is preferred to apply a high-dielectric coating on the backside of the substrate 1 to facilitate electrostatic chucking of the substrate 1 as in the method disclosed in JP-A-2003-501823. In the high-dielectric coating applied to the backside of the substrate 1 for this purpose, the electrical conductivity and the thickness of the constituent material are selected so as to have a sheet resistance of 100 Ω/square or below. The constituent material of the high-dielectric coating may be broadly selected from the ones disclosed in known references. For example, it is acceptable to use, as the constituent material, a coating having a high-dielectric constant as disclosed in JP-A-2003-501823, specifically, a coating of silicon, Ti, N, molybdenum, chromium, CrN or TaSi. The-high dielectric coating may have a thickness of, e.g., 10 to 1,000 nm, particularly 10 to 100 nm.

The high-dielectric coating may be deposited by a known deposition method, e.g., the sputtering method, such as magnetron sputtering or iron beam sputtering, the CVD method, the vacuum vapor deposition method or the electrolytic plating method.

The substrate 1 that is used in the method for depositing a reflective multilayer film, according to the present invention, is required to meet the characteristics as the substrate for an EUV mask blank. From this point of view, the substrate has a low thermal expansion coefficient (of preferably 0±1.0×10⁻⁷/° C., more preferably 0±0.3×10⁻⁷/° C., much more preferably 0±0.2×10⁻⁷/° C., further preferably 0±0.1×10⁻⁷/° C., particularly preferably 0±0.05×10⁻⁷/° C.). Preferably, the substrate is excellent in smoothness, flatness and resistance to a cleaning liquid to be used for, e.g., cleaning a photomask after formation of a mask blank or a pattern. Specifically, the substrate 1 may be made of glass having a low thermal expansion coefficient, such as SiO₂—TiO₂ glass. However, the substrate is not limited to be of this type. It is acceptable to use a substrate made of crystallized glass with a β-quartz solid solution precipitated, quartz glass, silicon, or metal. The substrate 1 preferably comprises a substrate having a high rigidity. Specifically, the substrate preferably has a specific rigidity of 3.0×10⁷ m²/s² or above and a Poisson's ratio of 0.16 to 0.25.

It is preferred from the viewpoint of obtaining a high reflectance and printing precision in a photomask after pattern formation that the substrate 1 be configured so that the surface for deposition has a surface smoothness of 0.15 nm or below in Rms and a flatness of 100 nm or below. On the other hand, it is preferred that the backside of the substrate 1 have a surface smoothness of 0.5 nm or below in Rms.

The dimensions and the thickness of the substrate 1 are properly determined according to the design values of a mask or the like. The substrate preferably comprises a square substrate with one side having a length of 140 to 160 mm and preferably comprises a substrate having a thickness of 5 to 7 mm. In the examples described later, each substrate is made of a square SiO₂—TiO₂ glass piece, which has one side having a length of 6 inch (152.4 mm) and a thickness of 0.25 inch (6.3 mm).

There are no particular limitations to the reflective multilayer film deposited on the substrate 1 by the method for depositing a reflective multilayer film, according to the present invention, as long as the deposited reflective multilayer film has desired characteristics as the reflective multilayer film for an EUV mask blank. The characteristic that is particularly required for the reflective multilayer film is that the reflective multilayer film comprises a film having a high EUV light reflectance. Specifically, the maximum value of the light reflectance is preferably 60% or more, more preferably 65% or more with respect to a wavelength in the vicinity of 13.5 nm when a ray in the wavelength range of the EUV light is applied on the surface of the reflective multilayer film.

Examples of the reflective multilayer film that satisfies the above-mentioned characteristic include an Si/Mo reflective multilayer film with Si films and Mo films alternately stacked therein, a Be/Mo reflective multilayer film with Be films and Mo films alternately stacked therein, a Si compound/Mo compound reflective multilayer film with Si compound films and Mo compound films alternately stacked therein, a Si/Mo/Ru reflective multilayer film with a Si film, an Mo film and a Ru film stacked in this order therein, and a Si/Ru/Mo/Ru reflective multilayer film with a Si film, an Ru film, a Mo film and a Ru film stacked in this order therein.

The process for depositing the above-mentioned reflective multilayer film may comprise a process, which is normally carried out when a reflective multilayer film is deposited by sputtering, such as magnetron sputtering or ion beam sputtering. For example, in the case of depositing a Si/Mo reflective multilayer film by ion beam sputtering, it is preferred that a Si film be deposited so as to have a thickness of 4.5 nm, using a Si target as the target, using an Ar gas (having a gas pressure of 1.3×10⁻² Pa to 2.7×10⁻² Pa) as the sputtering gas, applying an iron acceleration voltage of 300 to 1,500 V and setting the deposition rate at a value of 0.03 to 0.30 nm/sec., and then a Mo film be deposited so as to have a thickness of 2.3 nm, using a Mo target as the target, using an Ar gas (having a gas pressure of 1.3×10⁻² Pa to 2.7×10⁻² Pa) as the sputtering gas, applying an ion acceleration voltage of 300 to 1,500 V and setting the deposition rate at a value of 0.03 to 0.30 nm/sec. By stacking Si films and Mo films in 40 to 50 cycles, each of the cycles comprising the steps stated above, the Si/Mo reflective multilayer film is deposited. It is preferred from the viewpoint of obtaining an appropriate EUV light reflectance that the reflective multilayer film have a thickness of from 250 to 300 nm.

There is no limitation to the method for depositing the reflective multilayer film 2, as long as each film is deposited by sputtering. Both magnetron sputtering and iron beam sputtering are acceptable. It should be noted that it is preferred from the viewpoint of minimizing defects and obtaining a film having a high precision that each film be deposited by iron beam sputtering.

When the reflective multilayer film is deposited by sputtering, it is common that each film is deposited onto the substrate being rotated by a rotor for obtaining a uniform film thickness. It is preferred from the viewpoint of obtaining a uniformity film thickness that each film is deposited with the substrate being rotated by a rotor in the method for depositing a reflective multilayer film, according to present invention as well.

In the method for depositing a reflective multilayer film, according to the present invention, it is preferred from the viewpoint of preventing the surface of the reflective multilayer film from being oxidized after film deposition that the reflective multilayer film have a top layer comprising a layer, which is made of a material difficult to be oxidized. The layer, which is made of a material difficult to be oxidized, serves as a capping layer for the reflective multilayer film. A specific example of the layer, which serves as the capping layer and is made of a material difficult to be oxidized, is a Si layer. When the reflective multilayer film comprises a Si/Mo film, the top layer can serve as a capping layer by being formed from a Si layer. In that case, it is preferred that the capping layer have a film thickness of 11.0±1 nm.

As described in reference to FIG. 1(d) and FIG. 1(e), in the method for depositing a multilayer film, according to the present invention, after the reflective multilayer film 2 has been deposited, the substrate 1 is returned to the shape before deformation. When the substrate 1 is deformed into the shape shown in FIG. 1(c) by being held on the first electrostatic chuck 20 shown in FIG. 2, the chucking force of the first electrostatic chuck 20 may be removed to dismount the substrate 1 from the first electrostatic chuck 20 in order to return the substrate 1 to the shape before deformation. The substrate 1, which has been dismounted from the first electrostatic chuck 20, is returned to the shape before deformation by its restoring force.

As described in reference to FIG. 1(e), in the method for depositing a reflective multilayer film, according to the present invention, when the substrate 1 has been returned to the shape before deformation after the reflective multilayer film 2 has been deposited, the stress applied to the substrate by deposition of the reflective multilayer film 2 can be canceled by the first stress, with the result that the stress applied to the substrate by deposition of the reflective multilayer film is reduced to such a degree that the substrate is prevented from being deformed. Thus, the substrate 1 is prevented from being deformed by the stress applied to the substrate 1 by deposition of the multilayer film. Accordingly, the substrate 1 after deposition of the reflective multilayer film 2, more specifically, the substrate 1 that has been returned to the shape before deformation is excellent in flatness. The substrate 1 that has been returned to the shape before deformation has a flatness of preferably 100 nm or below, more preferably 75 nm or below, further preferably 50 nm or below, particularly preferably 30 nm or below. The “flatness of a substrate after deposition of a reflective multilayer film” means the flatness on the reflective multilayer film.

As a result, it is possible to obtain a reflective multilayer film for an EUV mask blank, which is excellent in flatness, more specifically a reflective multilayer film having a flatness of 100 nm or below.

Now, the first mode of the method for producing an EUV mask blank, according to the present invention will be described. The first mode of the method for producing an EUV mask blank, according to the present invention is a method for fabricating an EUV mask blank by depositing an absorbing layer on a reflective multilayer film by sputtering after depositing the reflective multilayer film on a substrate according to the method for depositing a reflective multilayer film, according to the present invention.

The first mode of the method for producing an EUV mask blank, according to the present invention is the same as the conventional methods in that the absorbing layer is deposited on the reflective multilayer film by sputtering, such as magnetron sputtering or iron beam sputtering.

However, in the first mode of the method for producing an EUV mask blank, according to the present invention, the absorbing layer is deposited in such a state that the substrate has been deformed so as to be subjected to the second stress.

Although described in detail later, in a case where the absorbing layer is deposited in such a state that the substrate has been deformed so as to be subjected to the second stress, when the substrate is returned to the original shape after deposition of the absorbing layer, the stress applied to the substrate by deposition of the absorbing layer can be canceled by the second stress, with the result that the stress applied to the substrate by deposition of the absorbing layer can be reduced to such a degree that the substrate is prevented from being deformed.

When the absorbing layer is deposited on the reflective multilayer film by sputtering, such as magnetron sputtering or iron beam sputtering, as in the case of depositing the reflective multilayer film on the substrate, a stress is caused in the absorbing layer after deposition, and the stress is applied to the substrate. This stress is called “the stress applied to the substrate by deposition of the absorbing layer” or “the stress caused by deposition of the absorbing layer” in Description.

However, the stress applied to the substrate by deposition of the reflective multilayer film and the stress applied to the substrate by deposition of the absorbing layer are different from each other in terms of magnitude since the reflective multilayer film and the absorbing layer are different from each other in terms of constituent material and deposition conditions. For example, when a TaN film having a thickness of 70 nm is deposited as the absorbing layer on the reflective multilayer film by iron beam sputtering, the substrate is subjected to a compressive stress of 100 to 400 MPa, which is caused by deposition of the absorbing layer.

The stress applied to the substrate by deposition of the absorbing layer is normally a compressive stress. However, the stress applied to the substrate by deposition of the absorbing layer is a tensile stress, depending on the material forming the absorbing layer, in some cases.

From this point of view, the first stress in the method for depositing a reflective multilayer film, according to the present invention, and the second stress in the method for producing an EUV mask blank, according to the present invention are normally different from each other in terms of magnitude. Both stresses are different from each other in terms of nature in some cases.

As is clear from the above-mentioned explanation, in the first mode of the method for producing an EUV mask blank, according to the present invention, the magnitude of the second stress varies according to the magnitude of the stress applied to the substrate by deposition of the absorbing layer.

In the first mode of the method for producing an EUV mask blank, according to the present invention, the stress applied to the substrate by deposition of the absorbing layer is reduced to preferably 300 MPa or below, more preferably 200 MPa or below, further preferably 100 MPa or below by the second stress.

In the first mode of the method for producing an EUV mask blank, according to the present invention, the concept that the substrate is deformed so as to be subjected to the second stress, and the means for deforming the substrate are basically the same as those referred to the case where the substrate is deformed so as to be subjected to the first stress in the method for depositing a reflective multilayer film, according to the present invention. It should be noted that the stress applied to the substrate by deposition of the absorbing layer is a tensile stress in some cases. From this point of view, the concept that the substrate is deformed so as to be subjected to the second stress, and the means for deforming the substrate will be described in connection with a case where the stress applied to the substrate by deposition of the absorbing layer is a tensile stress.

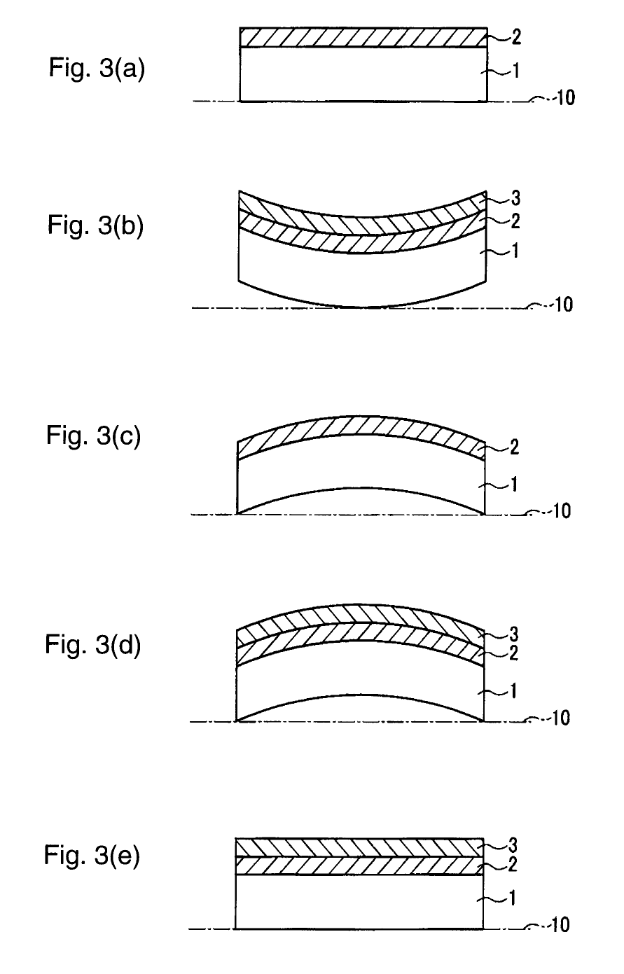

FIGS. 3(a) to 3(e) are schematic views explaining the first mode of the method for producing an EUV mask blank, according to the present invention and show shapes of the substrate before and after deposition of the absorbing layer. In FIGS. 3(a) to 3(e), the stress applied to the substrate by deposition of the absorbing layer is a tensile stress.

FIG. 3(a) shows the substrate 1 before deposition of the absorbing layer. In FIG. 3(a), the reflective multilayer film 2 has been deposited on the substrate 1. As shown in FIG. 3(a), the substrate 1 has a flatness of 0 μm before deposition of the absorbing layer. In FIG. 3(a), a line 10 is an imaginary horizontal line for more clearly showing the presence or absence of the deformation of the substrate 1.

FIG. 3(b) shows the substrate, wherein the absorbing layer 3 has been deposited on the reflective multilayer film 2 according to a conventional process. The substrate 1 shown in FIG. 3(b) is deformed so as to be warped in a concave shape toward the surface for deposition by the tensile stress caused by deposition of the absorbing layer 3.

FIG. 3(c) shows the substrate 1, which has been deformed so as to be subjected to the second stress in order that the substrate after deposition of the absorbing layer 3 is prevented from being deformed to the shape shown in FIG. 3(b). In FIG. 3(c), the substrate 1 is deformed so as to be warped in a convex shape toward the surface for deposition. In the first mode of the method for producing an EUV mask blank, according to the present invention, the absorbing layer is deposited by sputtering in such a state that the substrate 1 has been deformed into the shape shown in FIG. 3(c). FIG. 3(d) shows a state where the absorbing layer 3 has been deposited on the reflective multilayer film 2 on the substrate 1 shown in FIG. 3(c).

In the first mode of the method for producing an EUV mask blank, according to the present invention, an EUV mask blank is produced by depositing the absorbing layer 3 on the reflective multilayer film 2 in such a state that the substrate 1 has been deformed so as to be subjected to the second stress as shown in FIGS. 3(c) and 3(d), followed by returning the substrate 1 to the shape before deformation. In order that the substrate shown in FIG. 3(d) is returned to the shape before deformation, it is sufficient to remove the force that is applied to deform the substrate 1. The substrate 1 is returned to the shape before deformation by its restoring force. FIG. 3(e) shows a state where the substrate 1 has been returned to the shape before deformation after the absorbing layer 3 has deposited. In the state shown in FIG. 3(e), the stress applied to the substrate 1 by deposition of the absorbing layer 3 is canceled by the second stress, with the result that the stress applies to the substrate 1 by deposition of the absorbing layer can be reduced to such a degree that the substrate is prevented from being deformed. Thus, the substrate 1 after deposition of the absorbing layer 3 can be prevented from being deformed by the stress applied to the substrate 1 by deposition of the absorbing layer 3.

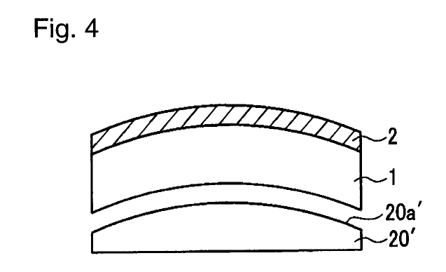

In the first mode of the method for producing an EUV mask blank, according to the present invention, a second electrostatic chuck, which has a contact surface with the substrate, formed in such a shape to correspond to the shape of the substrate after deformation, may hold the substrate 1 in order to deform the substrate 1 to the shape shown in FIG. 3(c). FIG. 4 is a schematic view of the second electrostatic chuck, which is utilized when the substrate 1 is deformed into the shape shown in FIG. 3(c). FIG. 4 also shows the substrate 1 shown in FIG. 3(c). In the second electrostatic chuck 20′ shown in FIG. 4, the contact surface 20a′ with the substrate 1 is formed in such a shape to correspond to the shape of the substrate 1 after deformation, which is shown in FIG. 3(c).

In the second electrostatic chuck 20′ shown in FIG. 4, the contact surface 20a′ with the substrate 1 correspond to the shape of the substrate 1 after deformation, which is shown in FIG. 3(c). Specifically, the contact surface 20a′ is formed in a convex shape and corresponds to the shape of the backside of the substrate 1 after deformation, which is shown in FIG. 3(c). The substrate 1 can be deformed into the shape shown in FIG. 3(c) by being held on the second electrostatic chuck 20′ formed in such a shape. Although the contact surface of the electrostatic chuck per se is formed in a convex shape in FIG. 4, a shaping member, which is formed in a convex shape, may be interposed between an electrostatic chuck and the substrate to provide the required convex shape, the electrostatic chuck having the contact surface formed in a planar shape. This modification is also covered by the concept of the electrostatic chuck.

When the second electrostatic chuck 20′ is formed in such a shape to correspond to the shape of the substrate 1 after deformation, the difference between the shape of the contact surface 20a′ of the second electrostatic chuck 20′ with the substrate 1, and the shape of the substrate 1 after deformation is preferably 2 mm or below at the maximum, more preferably 1 mm or below, further preferably 0.1 mm or below.

In the first mode of the method for producing an EUV mask blank, according to the present invention, the second electrostatic chuck is similar to the first electrostatic chuck in the method for depositing a reflective multilayer film, according to the present invention, in terms of Young's modulus, Poisson's ratio, chucking force, shape, dimensions and the like.

The reason why the second electrostatic chuck is utilized in the first mode of the method for producing an EUV mask blank, according to the present invention is that the first stress and the second stress normally have different magnitudes and different natures as described above. In other words, the electrostatic chuck (the first electrostatic chuck) 20, which is utilized when the substrate 1 is deformed so as to be subjected to the first stress, and the electrostatic chuck (the second electrostatic chuck) 20′, which is utilized when the substrate 1 is deformed so as to have subjected to the second stress are normally configured so that the contact surfaces 20a and 20a′ with the substrate 1 are different from each other in terms of shape. From this point of view, when the first stress and the second stress are the same as each other in terms of magnitude and nature, the first electrostatic chuck 20 and the second electrostatic chuck 20′ may comprise a single electrostatic chuck.

In the first mode of the method for producing an EUV mask blank, according to the present invention, examples of the material forming the absorbing layer 3 deposited on the reflective multilayer film include materials having a high absorption coefficient with respect to EUV light, specifically Cr, Ta or a nitride thereof. Among them, TaN is preferred because of being amorphous and having a smooth surface texture. It is preferred that the absorbing layer 3 have a thickness of from 50 to 150 nm. There is no limitation to the method for depositing the absorbing layer 3 as long as the absorbing layer is deposited by sputtering. Both of magnetron sputtering and ion beam sputtering are applicable.

The process for depositing the above-mentioned absorbing layer may comprise a process, which is normally carried out when an absorbing layer is deposited by sputtering, such as magnetron sputtering or ion beam sputtering. For example, when a TaN layer is deposited as the absorbing layer by ion beam sputtering, it is preferred that a Ta target be used as the target, and a N₂ gas (having a gas pressure of 5×10⁻³ Pa to 3×10⁻² Pa) be used as the sputtering gas to deposit the TaN layer so as to have a thickness of 50 to 150 nm at a voltage of 200 to 600 V and at a deposition rate of 0.05 to 0.3 nm/sec.

When depositing the absorbing layer by sputtering, it is preferred for the purpose of obtaining uniform deposition that the absorbing layer be deposited while the substrate is rotated by a rotor.

When producing an EUV mask blank, a buffer layer is deposited between the reflective multilayer film and the absorbing layer in some cases. In the method for depositing an EUV mask blank, according to the present invention as well, a buffer layer may be deposited between the reflective multilayer film and the absorbing layer. The second mode of the method for depositing an EUV mask blank, according to the present invention is a method for depositing an EUV mask blank by depositing a reflective multilayer film on a substrate by the method for depositing a reflective multilayer film, according to the present invention, followed by depositing a buffer layer on the reflective multilayer film and depositing an absorbing layer on the buffer layer by sputtering.

The second mode of the method for depositing an EUV mask blank, according to the present invention is the same as the first mode of the method for depositing an EUV mask blank, according to the present invention except that the buffer layer is deposited between the reflective multilayer film and the absorbing layer by sputtering.

In the second mode of the method for depositing an EUV mask blank, according to the present invention, examples of the material forming the buffer layer include Cr, Al, Ru, Ta, a nitride thereof, SiO₂, Si₃N₄ and Al₂O₃. It is preferred that the buffer layer have a thickness of from 10 to 60 nm.

There is no limitation to the method for depositing the buffer layer as long as the buffer layer is deposited by sputtering. Both of magnetron sputtering and ion beam sputtering are applicable.

The process for depositing the buffer layer may comprise a process, which is normally carried out when a buffer layer is deposited by sputtering, such as magnetron sputtering or ion beam sputtering. For example, it is preferred to deposit a film of SiO₂ by ion beam sputtering. When a film of SiO₂ is deposited as the buffer layer by ion beam sputtering, it is preferred that a Si target (with boron doped therein) be used as the target, and a combination of a gas of Ar and a gas of O₂ (having a gas pressure of 2.7×10⁻² Pa to 4.0×10⁻² Pa) be used as the sputtering gas to deposit the SiO₂ layer so as to have a thickness of 4 to 60 nm at a voltage of 1,200 to 1,500 V and at a deposition rate of 0.01 to 0.03 nm/sec.

When depositing the buffer layer by sputtering, it is preferred for the purpose of obtaining uniform deposition that the buffer layer be deposited while the substrate is rotated by a rotor.

In the second mode of the method for producing an EUV mask blank, according to the present invention, the absorbing layer is deposited in such a state that the substrate has been deformed so as to be subjected to the third stress.

In the second mode of the method for producing an EUV mask blank according to the present invention, an EUV mask blank is produced by depositing the buffer layer in such a state that the substrate has been deformed so as to be subjected to the third stress, and depositing the absorbing layer on the buffer layer, followed by returning the substrate to the original shape.

In the second mode of the method for producing an EUV mask blank, according to the present invention, when the substrate is returned to the original shape after deposition of the absorbing layer, the resultant of the stresses applied to the substrate by deposition of the buffer layer and the stresses applied to the substrate by deposition of the absorbing layer is canceled by the third stress, with the result that the resultant can be reduced to such a degree that the substrate is prevented from being deformed. Thus, the substrate after deposition of the buffer layer and the absorbing layer can be prevented from being deformed by the stresses applied to the substrate by deposition of the buffer layer and the absorbing layer.

In the method for producing an EUV mask blank, according to the present invention (the first mode and the second mode), the substrate 1 after deposition of the absorbing layer 3, more specifically, the substrate 1 that has been returned to the shape before deformation after the absorbing layer 3 has been deposited is excellent in flatness. The flatness of the substrate 1 that has been returned to the shape before deformation after the absorbing layer 3 has been deposited is preferably 100 nm or below, more preferably 75 nm or below, further preferably 50 nm or below, particularly preferably 30 nm or below. The “flatness of a substrate after deposition of an absorbing layer” means the flatness on the absorbing layer.

As a result, it is possible to produce an EUV mask blank having an excellent flatness, specifically, an EUV mask blank having a flatness of 100 nm or below.

In accordance with the method for depositing a reflective multilayer film, according to the present invention, a reflective multilayer film for an EUV mask blank can be obtained so as to have a flatness of 100 nm or below by using, as the substrate for deposition, a substrate having a flatness of more than 100 nm. In accordance with the method for producing an EUV mask blank, according to the present invention, an EUV mask blank can be produced so as to have a flatness of 100 nm or below by using, as the substrate for deposition, a substrate having a flatness of more than 100 nm.

In order to obtain a reflective multilayer film having a flatness of 100 nm or below for an EUV mask blank by using a substrate having a flatness of more than 100 nm, the substrate 1 is deformed so as to be subjected to the first stress in the state shown in FIG. 1(c) so that the substrate 1 has a flatness of 100 nm or below in the state shown in FIG. 1(e), estimating, based on, e.g., calculation, the shape of the substrate 1 in such a state that the substrate 1 is returned to the shape shown in FIG. 1(e), i.e., is returned to the shape before deformation after the reflective multilayer film 2 has been deposited.

Also when producing an EUV mask blank having a flatness of 100 nm or below by using a substrate having a flatness of more than 100 nm, the substrate 1 is deformed so as to be subjected to the second stress in the state shown in FIG. 3(c) so that the substrate 1 (EUV mask blank) has a flatness of 100 nm or below in the state shown in FIG. 3(e), estimating, based on, e.g., calculation, the shape of the substrate 1 (EUV mask blank) in such a state that the substrate 1 is returned to the shape shown in FIG. 3(e), i.e., is returned to the shape before deformation after the absorbing layer 3 has been deposited.

### EXAMPLES

Now, the present invention will be further described, based on examples.

### Comparative Example 1

In Comparative Example 1, a Si/Mo multilayer film is deposited without deforming a substrate.

The substrate for deposition comprises a SiO₂—TiO₂ glass substrate (having outer dimensions of 6 inch (152.4 mm) square and having a thickness of 6.3 mm). The glass substrate has a thermal expansion coefficient of 0.2×10⁻⁷/° C., a Young's modulus of 67 GPa, a Poisson's ratio of 0.17 and a specific rigidity of 3.07×10⁷ m²/s². The glass substrate is polished so as to have a surface smoothness of 0.15 nm or below in Rms and a flatness of 100 nm or below.

By magnetron sputtering, a Cr film having a thickness of 100 nm is deposited to apply a high-dielectric coating having a sheet resistance of 100 Ω/square on the backside of the glass substrate.

The Si/Mo reflective multilayer film is deposited so as to have a total thickness of 272 nm ((4.5 nm+2.3 nm)×40) by holding the glass substrate (having outer dimensions of 6 inch (152.4 mm) square and a thickness of 6.3 mm) on an ordinary electrostatic chuck formed in a flat shape, and alternately stacking Si films and Mo films in 40 repetition cycles by ion beam sputtering. The top layer of the Si/Mo reflective multilayer film comprises a Si layer (having a film thickness of 11.0 nm), which serves as a capping layer.

The deposition conditions for the Si films and the Mo films are as follows:

### Deposition Condition for the Si Films

Target: Si target (having boron doped therein)

Sputtering gas: Ar gas (having a gas pressure of 0.02 Pa)

Voltage: 700 V

Deposition rate: 0.077 nm/sec

Film thickness: 4.5 nm

### Deposition Conditions for the Mo Films

Target: Mo target

Sputtering gas: Ar gas (having a gas pressure of 0.02 Pa)

Voltage: 700 V

Deposition rate: 0.064 nm/sec

Film thickness: 2.3 nm

When the chucking force of the electrostatic chuck is removed to dismount the substrate from the electrostatic chuck after completion of deposition, the substrate is deformed so as to be warped in a convex shape toward the surface for deposition as shown in FIG. 1(b). When the amount of deformation of the most warped portion of the substrate is measured by a laser interferometer, it is confirmed that the amount of deformation is 2 μm.

### Example 1

In this example, a Si/Mo reflective multilayer film is deposited in the same process as Comparative Example 1 except that the first electrostatic chuck 20, which has the surface for deposition 20a formed in a concave shape shown in FIG. 2 is used as the electrostatic chuck. The surface for deposition 20a in the first electrostatic chuck 20 is formed so as to be deformed in the opposite direction to the direction in which the substrate 1 has been deformed after deposition of the reflective multilayer film 2 in Comparative Example 1 (in which the substrate 1 has been deformed so as to be warped in a convex shape toward the surface for deposition), i.e., is formed in a concave shape. The concave shape in the surface for deposition 20a has a depth of 2 μm.

When the Si/Mo reflective multilayer film is deposited, the substrate 1 that is held on the first electrostatic chuck 20 is deformed so as to be warped in a concave shape toward the surface for deposition shown in FIGS. 1(c) and (d). After the Si/Mo reflective multilayer film has been deposited, the chucking force of the first electrostatic chuck 20 is removed to dismount the substrate 1 from the first electrostatic chuck 20. The substrate 1 is returned to the shape before deformation by its restoring force, and no deformation in the substrate is found. When the flatness of the substrate 1 is measured by the laser interferometer, it is confirmed that the flatness is 0.1 μm.

### Comparative Example 2

In Comparative Example 2, the substrate that has had the Si/Mo reflective multilayer film deposited thereon in Example 1 is held on an electrostatic chuck formed in a flat shape, and an absorbing layer is deposited on the Si/Mo reflective multilayer film, producing an EUV mask blank. The deposition process is carried out to deposit, as the absorbing layer, a Cr film having a thickness of 70 nm by ion beam sputtering. The deposition conditions for the Cr film are as follows:

### Deposition Conditions for the Cr Film

Target: Cr target

Sputtering gas: Ar gas (having a gas pressure of 3.3×10⁻² Pa)

Voltage: 700 V

Deposition rate: 0.082 nm/sec

Film thickness: 70 nm

When the chucking force of the electrostatic chuck is removed to dismount the substrate from the electrostatic chuck after deposition of the Cr film, the substrate is deformed so as to be warped in a convex shape toward the surface for deposition (is deformed in the same shape as the shape shown in FIG. 1(b)). When the amount of deformation of the most warped portion of the substrate is measured by the laser interferometer, it is confirmed that the amount of deformation is 2 μm.

### Example 2

In this example, a Cr film is deposited in the same process as Comparative Example 2 except that the electrostatic chuck 20, which has the surface for deposition 20a formed in a concave shape shown in FIG. 2 is used as the second electrostatic chuck. The surface for deposition in the electrostatic chuck 20 is formed so as to be deformed in the opposite direction to the direction in which the substrate 1 has been deformed after deposition of the absorbing layer 3 in Comparative Example 2 (in which the substrate 1 has been deformed so as to be warped in a convex shape toward the surface for deposition), i.e., is deformed in a concave shape. The surface for deposition 20a in the electrostatic chuck is formed in a concave shape having a depth of 2 μm.

When the Cr film is deposited, the substrate that is held on the electrostatic chuck 20 is deformed so as to be warped in a concave shape toward the surface for deposition (is deformed in the same shape as the shape shown in FIGS. 1(c) and (d)). After the Cr film has been deposited, the substrate is removed from the electrostatic chuck. The substrate is returned to the shape before deformation by its restoring force, and no deformation in the substrate is found. When the flatness of the substrate is measured by the laser interferometer, it is confirmed that the flatness is 0.1 μm.

The entire disclosure of Japanese Patent Application No. 2005-325769 filed on Nov. 10, 2005 including specification, claims, drawings and summary is incorporated herein by reference in its entirety.

What is claimed is:

1. A method for depositing a multilayer film on a substrate, comprising:
depositing a multilayer film in such a state that a substrate has been deformed so as to be subjected to a stress, which is directed to the opposite direction to a stress applied to the substrate by deposition of the multilayer film; and
returning the substrate to the shape before deformation, after deposition of the multilayer film.

2. A method for depositing, on a substrate, a reflective multilayer film of a reflective mask blank for EUV lithography by sputtering, comprising:
depositing a reflective multilayer film in such a state that a substrate has been deformed so as to be subjected to a stress, which is directed to the opposite direction to a stress applied to the substrate by deposition of the reflective multilayer film; and
returning the substrate to the shape before deformation, after deposition of the reflective multilayer film.

3. The method according to claim 2, wherein the substrate that has been returned to the shape before deformation has a flatness of 100 nm or below.

4. The method according to claim 2, wherein in order to deposit the reflective multilayer film in such a state that the substrate has been deformed, the substrate is held by a first electrostatic chuck, which has a contact surface with the substrate, formed in a shape corresponding to the shape of the substrate after deformation.

5. The method according to claim 4, wherein the first electrostatic chuck has a chucking force of 0.5 kPa or above and a Young's modulus of 10 GPa or above.

6. The method according to claim 4, wherein the contact surface of the first electrostatic chuck, on which the substrate is held, has slightly smaller dimensions than those of the substrate.

7. The method according to claim 2, wherein the substrate has a specific rigidity of 3.0×10⁷ m²/s² or above and a Poisson's ratio of 0.16 to 0.25.

8. A method for producing a reflective mask blank for EUV lithography, comprising:
depositing an absorbing layer on a reflective multilayer film by sputtering after depositing the reflective multilayer film on a substrate by the method for depositing a reflective multilayer film of a reflective mask blank for EUV lithography, defined in claim 2;
the method further comprising:
depositing the absorbing layer in such a state that the substrate has been deformed so as to be subjected to a stress, which is directed to the opposite direction to a stress applied to the substrate by deposition of the absorbing layer; and
returning the substrate to the shape before deformation, after deposition of the absorbing layer.

9. The method according to claim 8, wherein the substrate that has been returned to the shape before deformation has a flatness of 100 nm or below.

10. The method according to claim 8, wherein in order to deposit the absorbing layer in such a state that the substrate has been deformed, the substrate is held by a second electrostatic chuck, which has a contact surface with the substrate, formed in a shape corresponding to the shape of the substrate after deformation.

11. A method for producing a reflective mask blank for EUV lithography, comprising:
depositing a buffer layer and an absorbing layer on a reflective multilayer film by sputtering after depositing the reflective multilayer film on a substrate by the method for depositing a reflective multilayer film of a reflective mask blank for EUV lithography, defined in claim 2;
the method further comprising:
depositing the buffer layer and the absorbing layer in such a state that the substrate has been deformed so as to be subjected to a stress, which is directed to the opposite direction to a stress applied to the substrate by deposition of the buffer layer and the absorbing layer; and
returning the substrate to the shape before deformation, after deposition of the absorbing layer.

12. The method according to claim 11, wherein the substrate that has been returned to the shape before deformation has a flatness of 100 nm or below.

13. The method according to claim 11, wherein in order to deposit the absorbing layer in such a state that the substrate has been deformed, the substrate is held by a second electrostatic chuck, which has a contact surface with the substrate, formed in a shape corresponding to the shape of the substrate after deformation.

14. The method according to claim 11, wherein in order to deposit the buffer layer and the absorbing layer in such a state that the substrate has been deformed, the substrate is held by a second electrostatic chuck, which has a contact surface with the substrate, formed in a shape corresponding to the shape of the substrate after deformation.

15. The method according to claim 13, wherein the second electrostatic chuck has a chucking force of 0.5 kPa or above and a Young's modulus of 10 GPa or above.
